(19) United States
(12) Patent Application Publication
(10) Pub. No.: US 2016/0079967 A1
(43) Pub. Date: Mar. 17, 2016

(54) POWER SEMICONDUCTOR DEVICE AND GATE DRIVER CIRCUIT

(71) Applicant: Kabushiki Kaisha Toshiba, Tokyo (JP)

(72) Inventor: Ryota Miwa, Kawasaki Kanagawa (JP)

(21) Appl. No.: 14/644,759

(22) Filed: Mar. 11, 2015

(30) Foreign Application Priority Data
Sep. 11, 2014 (JP) 2014-185316

(51) Int. Cl. H03K 3/356; H03K 3/017

(52) U.S. Cl. CPC H03K 3/356113; H03K 3/017

(57) ABSTRACT

A power semiconductor device includes a first output transistor connected to a first node at a first end of a current path thereof. The power semiconductor device further includes a second output transistor connected to a second end of the current path of the first output transistor at a first end of a current path thereof and to a second node at a second end of the current path. The power semiconductor device further includes a gate driver circuit that controls the first and second output transistors.

### CROSS-REFERENCE TO RELATED APPLICATION

This application is based upon and claims the benefit of priority from the prior Japanese Patent Application No. 2014-185316, filed on Sep. 11, 2014, the entire contents of which are incorporated herein by reference.

### BACKGROUND

1. Field

Embodiments described herein relate generally to a power semiconductor device and a gate driver circuit.

2. Background Art

A conventional half-bridge gate driver circuit includes a high side driver that drives a high side switching element, a low side driver that drives a low side switching element, and a level shifting circuit that shifts the level of a low side control signal and transmits the resulting signal to the high side driver to drive the high side switching element, for example.

The high side driver described above demodulates the control signal obtained by shifting the level of the input signal by means of an RS flip-flop circuit.

With the RS flip-flop circuit, input logics at the set terminal and the reset terminal are inhibited from being (1, 1). In other words, the set terminal and the reset terminal are inhibited from being at the “High” level at the same time. If such an input occurs, the value of the output signal is undefined (undefined state). In short, if the input logics at the set terminal and the reset terminal is (1, 1) as a result of the control signal with a shifted level being affected by a voltage noise, the output signal of the RS flip-flop circuit may become undefined.

If the control signal turns on the high side switching element while the low side switching element is in the off state, for example, the potential at the output terminal of the half-bridge gate driver circuit changes from 0V to the power supply potential of the high side power supply, and a voltage noise occurs. Then, a parasitic capacitor of a MOS transistor of the level shifting circuit is charged, so that the change of the control signal with the shifted level is delayed with respect to the change of the voltage at the output terminal.

That is, the control signal with the shifted level is affected by the voltage noise, and as a result, the inhibit logic signals (1, 1) are input to the set terminal and the reset terminal of the RS flip-flop circuit. In this way, the voltage noise can cause malfunction of the high side driver.

### BRIEF DESCRIPTION OF THE DRAWINGS

FIG. 1 is a circuit diagram showing an example of a configuration of a power semiconductor device 1000 according to a first embodiment.

FIG. 2 is a circuit diagram showing an example of a configuration of a latch circuit “LC” of the power semiconductor device 1000 shown in FIG. 1.

FIG. 3 is a waveform diagram showing an example of waveforms of signals of the latch circuit “LC” of the power semiconductor device 1000 shown in FIGS. 1 and 2.

### DETAILED DESCRIPTION

A power semiconductor device according to an embodiment includes a first output transistor connected to a first node at a first end of a current path thereof. The power semiconductor includes a second output transistor connected to a second end of the current path of the first output transistor at a first end of a current path thereof and to a second node at a second end of the current path. The power semiconductor includes a gate driver circuit that controls the first output transistor. The gate driver circuit includes a signal adjusting circuit that receives a set pulse signal and a reset pulse signal and outputs a first reset signal obtained by masking out a pulse of the reset pulse signal during a period in which the set pulse signal and the reset pulse signal overlap with each other. The gate driver circuit includes an RS flip-flop circuit that receives a first set signal responsive to the set pulse signal at a set terminal thereof, receives the first reset signal at a reset terminal thereof and outputs a first control signal. The gate driver includes a first driver that controls the first output transistor according to the first control signal.

In the following, an embodiment will be described with reference to the drawings.

### First Embodiment

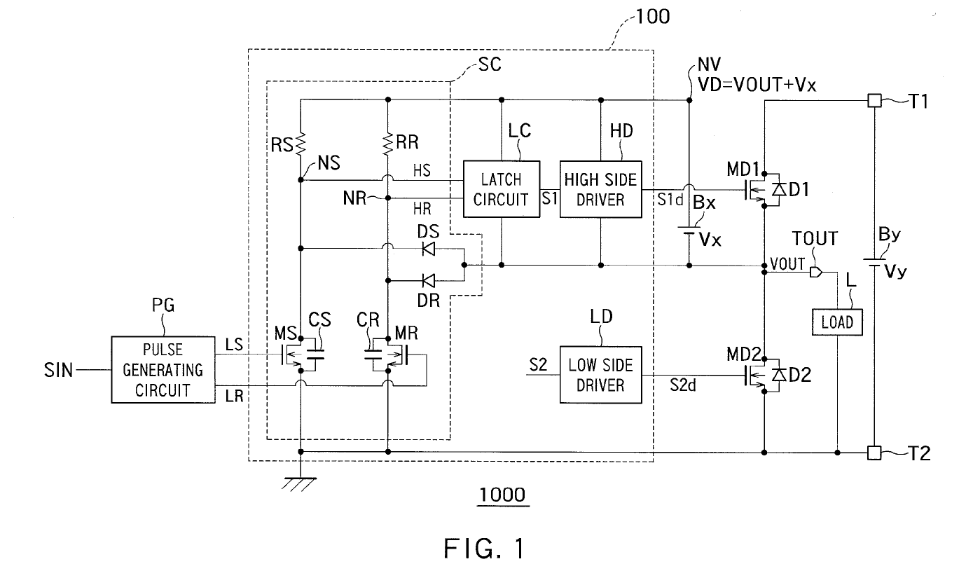

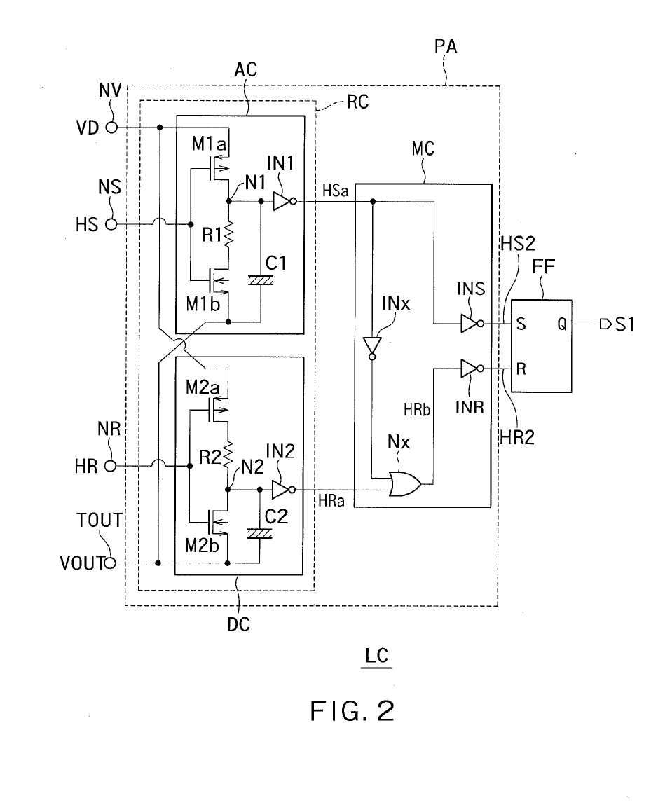

FIG. 1 is a circuit diagram showing an example of a configuration of a power semiconductor device 1000 according to a first embodiment. FIG. 2 is a circuit diagram showing an example of a configuration of a latch circuit “LC” of the power semiconductor device 1000 shown in FIG. 1.

As shown in FIG. 1, the power semiconductor device 1000 includes a driving direct-current power supply “Bx”, an output direct-current power supply “By”, an output terminal “TOUT”, a first output MOS transistor “MD1”, a second output MOS transistor “MD2”, a first output diode “D1”, a second output diode “D2”, a gate driver circuit 100, and a pulse generating circuit “PG”.

The driving direct-current power supply “Bx” outputs a power supply voltage “Vx”. The driving direct-current power supply “Bx” is connected to a power supply node (power supply terminal) “NV” at a positive electrode thereof and to the output terminal “TOUT” at a negative electrode thereof. The driving direct-current power supply “Bx” may be provided outside of the power semiconductor device 1000.

The output direct-current power supply “By” outputs a power supply voltage “Vy”. The output direct-current power supply “By” is connected to a power supply terminal “T1” at a positive electrode thereof. The output direct-current power supply “By” is connected to a ground via a power supply terminal “T2” at a negative electrode thereof as shown in FIG. 1, for example. The output direct-current power supply “By” may be provided outside of the power semiconductor device 1000.

The output terminal “TOUT” is connected to the negative electrode of the driving direct-current power supply “Bx”. An output voltage “VOUT” is output at the output terminal “TOUT”. A load “L” is connected between the output terminal “TOUT” and the negative electrode of the output direct-current power supply “By”.

The first output MOS transistor “MD1” is connected to the positive electrode of the output direct-current power supply “By” at one end (drain) of the current path thereof and to the output terminal “TOUT” at another end (source) of the current path thereof.

The first output diode “D1” is connected to the one end (drain) of the first output MOS transistor “MD1” at a cathode thereof and to the another end (source) of the first output MOS transistor “MD1” at an anode thereof.

The second output MOS transistor “MD2” is connected to the output terminal “TOUT” at one end (drain) of the current path thereof and to the negative electrode of the output direct-current power supply “By” at another end (source) of the current path thereof.

The second output diode “D2” is connected to the one end (drain) of the second output MOS transistor “MD2” at a cathode thereof and to the another end (source) of the second output MOS transistor “MD2” at an anode thereof.

The pulse generating circuit “PG” generates a set pulse signal “LS” and a reset pulse signal “LR” based on an input signal “SIN”. The pulse width of the set pulse signal “LS” and the pulse width of the reset pulse signal “LR” are set to be equal to each other, for example.

The gate driver circuit 100 controls the first and second output MOS transistors “MD1” and “MD2” based on the input signal “SIN” (the set pulse signal “LS” and the reset pulse signal “LR”).

The output voltage “VOUT” at the output terminal “TOUT” is controlled by the gate driver circuit 100 controlling the first and second output MOS transistors “MD1” and “MD2”.

As shown in FIG. 1, the gate driver circuit 100 includes a high side driver “HD”, a low side driver “LD”, a level shifting circuit “SC”, and a latch circuit “LC”, for example.

The high side driver “HD” outputs a first drive signal “S1d” according to a first control signal “S1”. The first drive signal “S1d” is input to a gate of the first output MOS transistor “MD1” to control the first output MOS transistor “MD1”.

The low side driver “LD” outputs a second drive signal “S2d” according to a second control signal “S2”. The second drive signal “S2d” is input to a gate of the second output MOS transistor “MD2” to control the second output MOS transistor “MD2”.

The level shifting circuit “SC” is connected between the power supply node “NV”, which is connected to the positive electrode of the driving direct-current power supply “Bx”, and the negative electrode of the output direct-current power supply “By”.

The level shifting circuit “SC” receives the set pulse signal “LS” and the reset pulse signal “LR” that are based on the input signal “SIN”. The level shifting circuit “SC” outputs a first set signal “HS”, which is obtained by shifting the level (increasing the amplitude) of the set pulse signal “LS”, and outputs a first reset signal “HR”, which is obtained by shifting the level (increasing the amplitude) of the reset pulse signal “LR”.

As shown in FIG. 1, the level shifting circuit “SC” includes a setting resistor “RS”, a setting MOS transistor “MS”, a resetting resistor “RR”, a resetting MOS transistor “MR”, a setting diode “DS”, and a resetting diode “DR”, for example.

The setting resistor “RS” is connected to the power supply node “NV” at one end thereof and to a first level node “NS” at another end thereof.

The setting MOS transistor “MS” is connected to the first level node “NS” at one end (drain) of the current path thereof and to the output direct-current power supply “By” at another end (source) of the current path thereof, and receives the set pulse signal “LS” at a gate thereof.

The setting MOS transistor “MS” has a parasitic capacitor “CS” between the one end (drain) thereof and the another end (source) thereof.

The resetting resistor “RR” is connected to the power supply node “NV” at one end thereof and to a second level node “NR” at another end thereof.

The resetting MOS transistor “MR” is connected to the second level node “NR” at one end (drain) thereof and to the negative electrode of the output direct-current power supply “By” at another end (source) thereof and receives the reset pulse signal “LR” at a gate thereof. The resetting MOS transistor “MR” has a parasitic capacitor “CR” between the one end (drain) thereof and the another end (source) thereof.

The setting diode “DS” is connected to the output terminal “TOUT” at an anode thereof and to the first level node “NS” at a cathode thereof.

The resetting diode “DR” is connected to the output terminal “TOUT” at an anode thereof and to the second level node “NR” at a cathode thereof.

For example, when the set pulse signal is at a “High” level, and the reset pulse signal “LR” is at a “Low” level, the setting MOS transistor “MS” is turned on, and the resetting MOS transistor “MR” is turned off.

In this case, the first level node “NS” is set at the “Low” level, and the second level node “NR” is set at the “High” level.

For example, when the set pulse signal and the reset pulse signal “LR” are at the “Low” level, the setting MOS transistor “MS” and the resetting MOS transistor “MR” are turned off.

In this case, the first level node “NS” and the second level node “NR” are set at the “Low” level (dead time).

For example, when the set pulse signal is at the “Low” level, and the reset pulse signal “LR” is at the “High” level, the setting MOS transistor “MS” is turned off, and the resetting MOS transistor “MR” is turned on.

In this case, the first level node “NS” is set at the “High” level, and the second level node “NR” is set at the “Low” level.

In short, the level shifting circuit “SC” turns on and off the setting MOS transistor “MS” and the resetting MOS transistor “MR” in a complementary manner with an interval of dead time according to the set pulse signal “LS” and the reset pulse signal “LR”.

The latch circuit “LC” outputs the first control signal “S1” according to a change of the pulse of the first set signal “HS” (the change from the “High” level to the “Low” level in this example) and a change of the pulse of the first reset signal “HR” (the change from the “High” level to the “Low” level in this example).

As shown in FIG. 2, the latch circuit “LC” includes a pulse width adjusting circuit “RC”, a filter circuit “MC”, and an RS flip-flop circuit “FF”, for example. The pulse width adjusting circuit “RC” and the filter circuit “MC” form a signal adjusting circuit “PA” that adjusts a signal input to the RS flip-flop circuit “FF”.

The pulse width adjusting circuit “RC” receives the first set signal “HS” and the first reset signal “HR”.

As shown in FIG. 2, the pulse width adjusting circuit “RC” includes a pulse width expanding circuit “AC” and a pulse width shrinking circuit “DC”, for example.

The pulse width expanding circuit “AC” expands the pulse width of the first set signal “HS” and outputs the resulting signal as an adjusted set signal “HSa”.

As shown in FIG. 2, the pulse width expanding circuit “AC” includes a first pMOS transistor “M1a”, a first resistor “R1”, a first nMOS transistor “M1b”, a first capacitor “C1”, and a first inverter “IN1”, for example.

The first pMOS transistor “M1a” is connected to the power supply node “NV” at a source thereof, to a first output node “N1” at a drain thereof and to the first level node “NS” at a gate thereof.

The first resistor “R1” is connected to the first output node “N1” at one end thereof.

The first nMOS transistor “M1b” is connected to another end of the first resistor “R1” at a drain thereof, to the output terminal “TOUT” at a source thereof, and to the first level node “NS” at a gate thereof.

The first capacitor “C1” is connected to the first output node “N1” at one end thereof and to the output terminal “TOUT” at another end thereof.

The first inverter “IN1” is connected to the first output node “N1” at an input thereof and outputs the adjusted set signal “HSa”, which is obtained by inverting the signal at the first output node “N1”.

Since the first set signal “HS” controls turning on and off of the first pMOS transistor “M1a” and the first nMOS transistor “M1b” in a complementary manner, the voltage at the first output node “N1” is represented by an inverted signal of the first set signal “HS”.

Since there is the first resistor “R1”, the voltage at the first output node “N1” quickly rises when the first pMOS transistor “M1a” is turned on and the first nMOS transistor “M1b” is turned off, and slowly falls when the first pMOS transistor “M1a” is turned off and the first nMOS transistor “M1b” is turned on.

Therefore, as described above, the adjusted set signal “HSa” is a signal obtained by expanding the pulse width of the first set signal “HS”.

The pulse width shrinking circuit “DC” shrinks the pulse width of the first reset signal “HR” and outputs the resulting signal as an adjusted reset signal “HRa”.

As shown in FIG. 2, the pulse width shrinking circuit “DC” includes a second pMOS transistor “M2a”, a second resistor “R2”, a second nMOS transistor “M2b”, a second capacitor “C2”, and a second inverter “IN2”, for example.

The second pMOS transistor “M2a” is connected to the power supply node “NV” at a source thereof and to the second level node “NR” at a gate thereof.

The second resistor “R2” is connected to a drain of the second pMOS transistor “M2a” at one end thereof and to a second output node “N2” at another end thereof.

The second nMOS transistor “M2b” is connected to the second output node “N2” at a drain thereof, to the output terminal “TOUT” at a source thereof, and to the second level node “NR” at a gate thereof.

The second capacitor “C2” is connected to the second output node “N2” at one end thereof and to the output terminal “TOUT” at another end thereof.

The second inverter “IN2” is connected to the second output node “N2” at an input thereof and outputs the adjusted reset signal “HRa”, which is obtained by inverting the signal at the second output node “N2”.

Since the first reset signal “HR” controls turning on and off of the second pMOS transistor “M2a” and the second nMOS transistor “M2b” in a complementary manner, the voltage at the second output node “N2” is represented by an inverted signal of the first reset signal “HR”.

Since there is the second resistor “R2”, the voltage at the second output node “N2” slowly rises when the second pMOS transistor “M2a” is turned on and the second nMOS transistor “M2b” is turned off, and quickly falls when the second pMOS transistor “M2a” is turned off and the second nMOS transistor “M2b” is turned on.

Therefore, as described above, the adjusted reset signal “HRa” is a signal obtained by shrinking the pulse width of the first reset signal “HR”.

As described above, the pulse width adjusting circuit “RC” makes an adjustment so that the pulse width of the adjusted set signal “HSa” is larger than the pulse width of the adjusted reset signal “HRa”.

The filter circuit “MC” receives the adjusted set signal “HSa” and the adjusted reset signal “HRa”.

The filter circuit “MC” is configured to filter (mask) the pulse signal of the adjusted reset signal “HRa” during a period in which the pulse signal of the adjusted reset signal “HRa” and the pulse signal of the adjusted set signal “HSa” overlap with each other.

As shown in FIG. 2, the filter circuit “MC” includes a first filtering inverter “INx”, a second filtering inverter “INS”, a third filtering inverter “INR”, and an OR circuit “Nx”, for example.

The first filtering inverter “INx” receives the adjusted set signal “HSa” and outputs an inverted signal of the adjusted set signal “HSa”.

The OR circuit “Nx” receives the adjusted reset signal “HRa” and the inverted signal of the adjusted set signal “HSa” and outputs a signal “HRb”.

The second filtering inverter “INS” receives the adjusted set signal “HSa” and outputs a second set signal “HS2”, which is an inverted signal of the adjusted set signal “HSa”.

The third filtering inverter “INR” receives the signal “HRb” output from the OR circuit “Nx” and outputs a second reset signal “HR2”, which is an inverted signal of the signal “HRb”.

The RS flip-flop circuit “FF” receives the second set signal “HS2” at a set terminal “S” thereof, receives the second reset signal “HR2” at a reset terminal “R” thereof, and outputs the first control signal “S1” at an output terminal “Q” thereof. As described above, the high side driver “HD” outputs the first drive signal “Sid” according to the first control signal “S1”.

Next, a principle will be described on which an erroneous pulse occurs in the first reset signal “HR” in a period in which a pulse of the set pulse signal “LS” occurs (the set pulse signal “LS” is at the “High” level) and no pulse of the reset pulse signal “LR” occurs (the reset pulse signal “LR” is at the “Low” level), and then, operational characteristics of the power semiconductor device 1000 configured as described above will be described.

When no pulse of the reset pulse signal “LR” occurs (the reset pulse signal “LR” is at the “Low” level), if the set pulse signal “LS” is set at the “High” level, the setting MOS transistor “MS” is turned on, while the resetting MOS transistor “MR” is in the off state.

In this case, the first set signal “HS” is set at the “Low” level, while the first reset signal “HR” is set at the “High” level.

At this point, if the second output MOS transistor “MD2” is turned off and the first output MOS transistor “MD1” is turned on in the power semiconductor device 1000, the output voltage “VOUT” at the output terminal “TOUT” increases from the ground voltage to the power supply voltage “Vy” of the output direct-current power supply “By”. As a result, a voltage “VD” at the power supply node “NV” increases from the power supply voltage “Vx” of the driving direct-current power supply “Bx” to the sum of the power supply voltage “Vy” and the power supply voltage “Vx”.

The parasitic capacitor “CR” of the resetting MOS transistor “MR” forming the level shifting circuit “SC” is charged, so that the first reset signal “HR” changes from the “High” level to the “Low” level. Then, when the charging is completed, the first reset signal “HR” changes from the “Low” level to the “High” level (an erroneous pulse occurs).

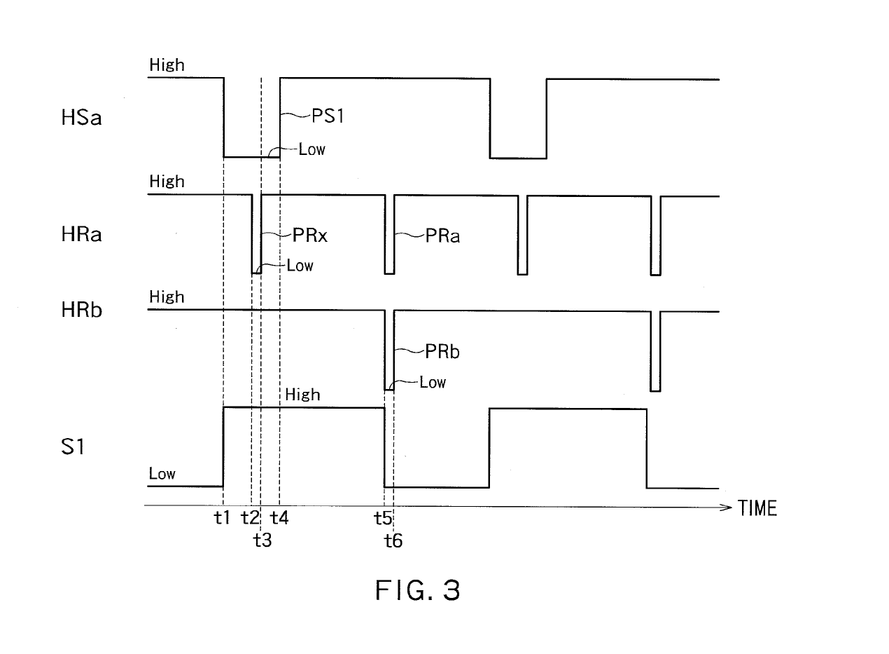

Thus, an erroneous pulse occurs in the first reset signal “HR”, even though no pulse of the reset pulse signal “LR” occurs. Therefore, an inhibit input logic (1, 1) is input to the set terminal and the reset terminal of the RS flip-flop circuit “FF”, and the output of the RS flip-flop circuit “FF” becomes undefined. Next, an example of operational characteristics of the power semiconductor device 1000 will be described. In this embodiment, the latch circuit “LC” performs an operation of filtering (masking) out the erroneous pulse that occurs in the first reset signal “HR”. FIG. 3 is a waveform diagram showing an example of waveforms of signals of the latch circuit “LC” of the power semiconductor device 1000 shown in FIGS. 1 and 2. In FIG. 3, the signals “HSa”, “HRa”, and “HRb” set at the “Low” level are defined as a pulse.

As described above, the pulse width expanding circuit “AC” of the latch circuit “LC” expands the pulse width of the first set signal “HS” (delays the trailing end of the pulse of the first set signal “HS”) and outputs the resulting signal as the adjusted set signal “HSa”.

Therefore, as shown in FIG. 3, in a period from a time “t1” to a time “t4”, a pulse “PS1” of the adjusted set signal “HSa” occurs.

On the other hand, as described above, the pulse width shrinking circuit “DC” shrinks the pulse width of the first reset signal “HR” (delays the leading end of the pulse of the first reset signal “HR”) and outputs the resulting signal as the adjusted reset signal “HRa”.

Since an erroneous pulse occurs in the first reset signal “HR” described above, a pulse “PRx” of the adjusted reset signal “HRa” occurs in a period from a time “t2” to a time “t3”.

Thus, the period in which the adjusted set signal “HSa” is set at the “Low” level includes the period in which the adjusted reset signal “HRa” is set at the “Low” level. This relationship allows the filter circuit “MC” to filter (mask) out the adjusted reset signal “HRa” with the adjusted set signal “HSa”. Therefore, any erroneous pulse can be eliminated from the filtered (masked) signal “HRb” (in the period from the time “t1” to the time “t4”).

In addition, since a normal pulse occurs in the first reset signal “HR”, a pulse “PRa” of the adjusted reset signal “HRa” occurs in a period from a time “t5” to a time “t6”. In this period, however, no pulse of the adjusted set signal “HSa” occurs. In the filtered (masked) signal “HRb”, a normal pulse “PRb” occurs.

As described above, the filter circuit “MC” outputs a second set signal “HS2” including a pulse corresponding to a pulse of the adjusted set signal “HSa” (an inverted signal of the adjusted set signal “HSa”). In addition, the filter circuit “MC” outputs a second reset signal “HR2” including a pulse corresponding to a pulse of the adjusted reset signal “HRa” that remains after any pulse of the adjusted reset signal “HRa” that occurs in a period that overlaps with the period in which a pulse of the adjusted set signal “HSa” occurs is filtered out (an inverted signal of the signal “HRb”).

In short, the filter circuit “MC” outputs the second set signal “HS2” and the second reset signal “HR2” in order to prevent a truth value of the output of the RS flip-flop circuit “FF” from being undefined.

Therefore, the input logics at the set terminal “S” and the reset terminal “R” of the RS flip-flop circuit “FF” are prevented from being (1, 1). In other words, the set terminal “S” and the reset terminal “R” of the RS flip-flop circuit “FF” are prevented from being at the “High” level at the same time.

Therefore, the period in which the first control signal “S1” output from the RS flip-flop circuit “FF” is undefined is eliminated, and malfunction of the high side driver “HD” can be avoided.

In this embodiment, description of specific control of the low side driver “LD” and the second output MOS transistor “MD2” has been omitted.

As described above, the power semiconductor device according to the first embodiment can prevent malfunction of the high side driver.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a first output transistor connected to a first node at a first end of a current path thereof;
a second output transistor connected to a second end of the current path of the first output transistor at a first end of a current path thereof and to a second node at a second end of the current path; and
a gate driver circuit that controls the first output transistor,
wherein the gate driver circuit comprises:
a signal adjusting circuit that receives a set pulse signal and a reset pulse signal and outputs a first reset signal obtained by masking out a pulse of the reset pulse signal during a period in which the set pulse signal and the reset pulse signal overlap with each other;
an RS flip-flop circuit that receives a first set signal responsive to the set pulse signal at a set terminal thereof, receives the first reset signal at a reset terminal thereof and outputs a first control signal; and
a first driver that controls the first output transistor according to the first control signal.

2. The power semiconductor device according to claim 1, wherein the signal adjusting circuit comprises:
a pulse width adjusting circuit that makes an adjustment so that the pulse width of the set pulse signal is larger than the pulse width of the reset pulse signal.

3. The power semiconductor device according to claim 1, wherein the gate driver circuit further comprises:
a level shifting circuit that shifts levels of the set pulse signal and the reset pulse signal.

4. The power semiconductor device according to claim 1, wherein the gate driver circuit further comprises:
a level shifting circuit that outputs a second set signal and a second reset signal obtained by shifting levels of the set pulse signal and the reset pulse signal, respectively,
the signal adjusting circuit makes an adjustment so that the pulse width of the second set signal is larger than the pulse width of the second reset signal and outputs a third set signal and a third reset signal, and
the first reset signal is a pulse signal obtained by masking out a pulse of the third reset signal in a period in which the third set signal and the third reset signal overlaps with each other.

5. The power semiconductor device according to claim 4, wherein the signal adjusting circuit comprises:
a pulse width expanding circuit that expands the pulse width of the second set signal and outputs the resulting signal as the third set signal; and
a pulse width shrinking circuit that shrinks the pulse width of the second reset signal and outputs the resulting signal as the third reset signal.

6. The power semiconductor device according to claim 1, further comprising:
a pulse generating circuit that generates the set pulse signal and the reset pulse signal based on an input signal.

7. The power semiconductor device according to claim 1, wherein the second node is connected to a ground.

8. The power semiconductor device according to claim 1, wherein the gate driver circuit outputs the first set signal and the first reset signal so that a truth value of an output of the RS flip-flop circuit is prevented from being undefined.

9. The power semiconductor device according to claim 3, wherein the level shifting circuit comprises:
a setting resistor connected to a third node at a first end thereof;
a setting transistor connected to a second end of the setting resistor at a first end of a current path thereof and to the second node at a second end of the current path, receives the set pulse signal at a control end thereof and has a parasitic capacitor between the first end and the second end;
a resetting resistor connected to the third node at a first end thereof;
a resetting transistor connected to a second end of the resetting resistor at a first end of a current path thereof and to the second node at a second end of the current path, receives the reset pulse signal at a control end thereof and has a parasitic capacitor between the first end and the second end;
a setting diode connected to the second end of the first output transistor at an anode thereof and to the second end of the setting resistor at a cathode thereof; and
a resetting diode connected to the anode of the setting diode at an anode thereof and to the second end of the resetting resistor at a cathode thereof,
wherein the setting transistor and the resetting transistor are turned on and off in a complementary manner with an interval of dead time according to the set pulse signal and the reset pulse signal.

10. The power semiconductor device according to claim 5,
wherein the pulse width expanding circuit comprises:
a first transistor of a first conductivity type that is connected to a third node at a first end of a current path thereof, and receives the second set signal at a control end thereof;
a first resistor that is connected to a second end of the current path of the first transistor at a first end thereof;
a second transistor of a second conductivity type that is connected to the second end of the first resistor at a first end of a current path thereof, to the second end of the current path of the first output transistor at a second end of the current path thereof, and receives the second set signal at a control end thereof; and
a first capacitor that is connected to the second end of the current path of the first transistor at a first end thereof, and to the second end of the current path of the second transistor at a second end thereof, and
wherein the pulse width shrinking circuit comprises:
a third transistor of the first conductivity type that is connected to the third node at a first end of a current path thereof, and receives the second reset signal at a control end thereof;
a second resistor that is connected to a second end of the current path of the third transistor at a first end thereof;
a fourth transistor of the second conductivity type that is connected to the second end of the second resistor at a first end of a current path thereof, to the second end of the current path of the first output transistor at a second end of the current path thereof, and receives the second reset signal at a control end thereof; and
a second capacitor that is connected to the first end of the current path of the fourth transistor at a first end thereof, and to the second end of the current path of the fourth transistor at a second end thereof.

11. A gate driver circuit that controls a first output transistor connected to a first node at a first end of a current path thereof and a second output transistor connected to a second end of the current path of the first output transistor at a first end of a current path thereof and to a second node at a second end of the current path,
wherein the gate driver circuit comprises:
a signal adjusting circuit that receives a set pulse signal and a reset pulse signal and outputs a first reset signal obtained by masking out a pulse of the reset pulse signal during a period in which the set pulse signal and the reset pulse signal overlap with each other;
an RS flip-flop circuit that receives a first set signal responsive to the set pulse signal at a set terminal thereof, receives the first reset signal at a reset terminal thereof and outputs a first control signal; and
a first driver that controls the first output transistor according to the first control signal.

12. The gate driver circuit according to claim 11, wherein the signal adjusting circuit comprises:
a pulse width adjusting circuit that makes an adjustment so that the pulse width of the set pulse signal is larger than the pulse width of the reset pulse signal.

13. The gate driver circuit according to claim 11, further comprising:
a level shifting circuit that shifts levels of the set pulse signal and the reset pulse signal.

14. The gate driver circuit according to claim 11, further comprising:
a level shifting circuit that outputs a second set signal and a second reset signal obtained by shifting levels of the set pulse signal and the reset pulse signal, respectively,
wherein the signal adjusting circuit makes an adjustment so that the pulse width of the second set signal is larger than the pulse width of the second reset signal and outputs a third set signal and a third reset signal, and
wherein the first reset signal is a pulse signal obtained by masking out a pulse of the third reset signal in a period in which the third set signal and the third reset signal overlaps with each other.

15. The gate driver circuit according to claim 14, wherein the signal adjusting circuit comprises:
a pulse width expanding circuit that expands the pulse width of the second set signal and outputs the resulting signal as the third set signal; and
a pulse width shrinking circuit that shrinks the pulse width of the second reset signal and outputs the resulting signal as the third reset signal.

16. The gate driver circuit according to claim 11, further comprising:
a pulse generating circuit that generates the set pulse signal and the reset pulse signal based on an input signal.

17. The gate driver circuit according to claim 11, wherein the second node is connected to a ground.

18. The gate driver circuit according to claim 11, wherein the gate driver circuit outputs the first set signal and the first reset signal so that a truth value of an output of the RS flip-flop circuit is prevented from being undefined.

19. The gate driver circuit according to claim 13, wherein the level shifting circuit comprises:
a setting resistor connected to a third node at a first end thereof;
a setting transistor connected to a second end of the setting resistor at a first end of a current path thereof and to the second node at a second end of the current path, receives the set pulse signal at a control end thereof and has a parasitic capacitor between the first end and the second end;
a resetting resistor connected to the third node at a first end thereof;
a resetting transistor connected to a second end of the resetting resistor at a first end of a current path thereof and to the second node at a second end of the current path, receives the reset pulse signal at a control end thereof and has a parasitic capacitor between the first end and the second end;
a setting diode connected to the second end of the first output transistor at an anode thereof and to the second end of the setting resistor at a cathode thereof; and
a resetting diode connected to the anode of the setting diode at an anode thereof and to the second end of the resetting resistor at a cathode thereof, and
the setting transistor and the resetting transistor are turned on and off in a complementary manner with an interval of dead time according to the set pulse signal and the reset pulse signal.

20. The gate driver circuit according to claim 12,
wherein the pulse width expanding circuit comprises:
a first transistor of a first conductivity type that is connected to a third node at a first end of a current path thereof, and receives the second set signal at a control end thereof;
a first resistor that is connected to a second end of the current path of the first transistor at a first end thereof;
a second transistor of a second conductivity type that is connected to the second end of the first resistor at a first end of a current path thereof, to the second end of the current path of the first output transistor at a second end of the current path thereof, and receives the second set signal at a control end thereof; and
a first capacitor that is connected to the second end of the current path of the first transistor at a first end thereof, and to the second end of the current path of the second transistor at a second end thereof, and
wherein the pulse width shrinking circuit comprises:
a third transistor of the first conductivity type that is connected to the third node at a first end of a current path thereof, and receives the second reset signal at a control end thereof;
a second resistor that is connected to a second end of the current path of the third transistor at a first end thereof;
a fourth transistor of the second conductivity type that is connected to the second end of the second resistor at a first end of a current path thereof, to the second end of the current path of the first output transistor at a second end of the current path thereof, and receives the second reset signal at a control end thereof; and
a second capacitor that is connected to the first end of the current path of the fourth transistor at a first end thereof, and to the second end of the current path of the fourth transistor at a second end thereof.
